(19) United States
(12) Patent Application Publication
(10) Pub. No.: US 2014/0048750 A1
(43) Pub. Date: Feb. 20, 2014

(54) CONDUCTIVE PASTE COMPOSITION FOR INTERNAL ELECTRODE AND MULTILAYERED CERAMIC ELECTRONIC COMPONENT CONTAINING THE SAME

(71) Applicant: SAMSUNG ELECTRO-MECHANICS CO., LTD., Gyunggi-do (KR)

(72) Inventors: Jong Han KIM, Gyunggi-do (KR); Eung Soo KIM, Gyunggi-do (KR); Seung Ho LEE, Gyunggi-do (KR); Jae Yeol CHOI, Gyunggi-Do (KR)

(73) Assignee: SAMSUNG ELECTRO-MECHANICS CO., LTD., Gyunggi-do (KR)

(21) Appl. No.: 13/660,583

(22) Filed: Oct. 25, 2012

(30) Foreign Application Priority Data
Aug. 20, 2012 (KR) 10-2012-0090689

(51) Int. Cl. H01B 1/02; H01C 7/13; H01F 5/00; H01G 4/12; H01L 41/00; H01C 7/10; B82Y 99/00; B82Y 30/00

(52) U.S. Cl. 252/513; 310/311; 338/22 R; 338/21; 336/200; 361/321.2; 252/512; 977/777; 977/810; 977/811; 977/932

(57) ABSTRACT

There is provided a conductive paste composition for an internal electrode of a multilayered ceramic electronic component including: a metal powder; and a chrome (Cr) or cobalt (Co) powder having a melting point higher than that of the metal powder. In the conductive paste composition for the internal electrode, the sintering shrinkage temperature of the internal electrode may be increased, and the connectivity of the internal electrode may be improved.

### CROSS-REFERENCE TO RELATED APPLICATIONS

This application claims the priority of Korean Patent Application No. 10-2012-0090689 filed on Aug. 20, 2012, in the Korean Intellectual Property Office, the disclosure of which is incorporated herein by reference.

### BACKGROUND OF THE INVENTION

1. Field of the Invention

The present invention relates to a conductive paste composition for an internal electrode and a multilayer ceramic electronic component containing the same, and more particularly, to a conductive paste composition for an internal electrode capable of controlling sintering shrinkage of a metal powder and a multilayer ceramic electronic component containing the same.

2. Description of the Related Art

Generally, electronic components using a ceramic material, such as a capacitor, an inductor, a piezoelectric element, a varistor, or a thermistor, or the like, include a ceramic body formed of a ceramic material, internal electrode layers formed within the ceramic body, and external electrodes mounted on surfaces of the ceramic body to be connected to the internal electrode layers.

Among the ceramic electronic components, a multilayered ceramic capacitor includes a plurality of multilayered dielectric layers, internal electrode layers disposed to face each other, having the dielectric layer interposed therebetween, and external electrodes electrically connected to the internal electrode layers.

Multilayered ceramic capacitors have been widely used as components for mobile communications devices such as portable computers, personal digital assistants (PDAs), mobile phones, and the like, due to advantages thereof such as small size, high capacitance, ease of mounting, and the like.

In accordance with the recent trend for high performance and slimness and lightness of products within the electrical and electronics industries, miniaturization, high performance, and low price have been demanded in electronic components.

In particular, as CPU speeds have increased and products have been slimmed, digitalized, multi-functionalized and made lightweight; research into technologies for implementing characteristics such as miniaturization, thinness, high capacitance, low impedance in at a high frequency region, and the like, of a multilayered ceramic capacitor (hereinafter, referred to as an MLCC) has been actively undertaken.

The multilayered ceramic capacitor may be manufactured by stacking and co-firing conductive pastes for an internal electrode and ceramic green sheets by a sheet method, a printing method, or the like.

However, in order to form the dielectric layers, the ceramic green sheets may be fired at a high temperature of about 1100° C. or more, and the conductive paste may be sintering-shrunken at a temperature lower than the firing temperature of the ceramic green sheet.

Therefore, overfiring of the internal electrode layer may occur during the ceramic green sheet firing process, such that the internal electrode layer may be agglomerated or disconnected, and connectivity of the internal electrode layer may be deteriorated.

### RELATED ART DOCUMENT

Japanese Patent Laid-Open Publication No. JP 1998-324906

### SUMMARY OF THE INVENTION

An aspect of the present invention provides a conductive paste composition for an internal electrode capable of controlling a sintering shrinkage of a metal powder, and a multilayered ceramic electronic component containing the same.

According to an aspect of the present invention, there is provided a conductive paste composition for an internal electrode of a multilayered ceramic electronic component, the conductive paste composition including: a metal powder; and a chrome (Cr) or cobalt (Co) powder having a melting point higher than that of the metal powder.

The chrome (Cr) or cobalt (Co) powder may have a content of 1 to 20 parts by weight based on 100 parts by weight of the metal powder.

The metal powder may be at least one selected from the group consisting of nickel (Ni), manganaese (Mn), chromium (Cr), cobalt (Co), aluminum (Al), and alloys thereof.

The metal powder may have an average particle size of 50 to 400 nm.

The chrome (Cr) or cobalt (Co) powder may have an average particle size of 10 to 100 nm.

According to another aspect of the present invention, there is provided a multilayered ceramic electronic component including: a ceramic body; and internal electrode layers formed in the ceramic body, wherein the internal electrode layers include a chrome (Cr) or cobalt (Co) powder trapped therein, the chrome (Cr) or cobalt (Co) powder having a melting point higher than that of a metal powder forming the internal electrode layers.

The chrome (Cr) or cobalt (Co) powder may be partially oxidized.

The internal electrode layers may have a metal layer formed of the chrome (Cr) or cobalt (Co) powder on an interface thereof.

The chrome (Cr) or cobalt (Co) powder may be partially oxidized.

The metal powder may be at least one selected from the group consisting of nickel (Ni), manganaese (Mn), chromium (Cr), cobalt (Co), aluminum (Al), and alloys thereof.

The chrome (Cr) or cobalt (Co) powder may have a content of 1 to 20 parts by weight based on 100 parts by weight of the metal powder.

The metal powder may have an average particle size of 50 to 400 nm.

The chrome (Cr) or cobalt (Co) powder may have an average particle size of 10 to 100 nm.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic perspective view illustrating the multilayered ceramic capacitor according to an embodiment of the present invention;

FIG. 2 is a schematic cross-sectional view illustrating a multilayered ceramic capacitor taken along line A-A′ of FIG. 1;

FIG. 3 is a partially enlarged view schematically illustrating an internal electrode according to an embodiment of the present invention; and

FIGS. 4A and 4B are diagrams schematically illustrating a sintering shrinkage behavior of a conductive paste for an internal electrode according to an embodiment of the present invention.

### DETAILED DESCRIPTION OF THE EMBODIMENTS

Embodiments of the present invention will now be described in detail with reference to the accompanying drawings.

The embodiments of the present invention may be modified in many different forms and the scope of the invention should not be limited to the embodiments set forth herein. Rather, these embodiments are provided so that this disclosure will be thorough and complete, and will fully convey the concept of the invention to those skilled in the art. Therefore, in the drawings, the shapes and dimensions may be exaggerated for clarity, and the same reference numerals will be used throughout to designate the same or like components.

An embodiment of the present invention relates to a ceramic electronic component. As an example of the electronic component using a ceramic material, a capacitor, an inductor, a piezoelectric element, a varistor, or a thermistor, or the like may be provided. Hereinafter, a multilayered ceramic capacitor as an example of the ceramic electronic component will be described.

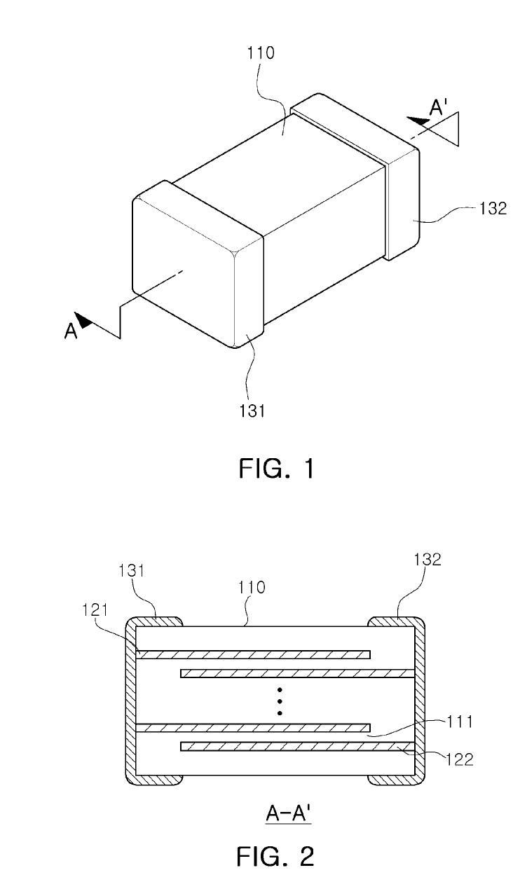

FIG. 1 is a schematic perspective view illustrating the multilayered ceramic capacitor according to an embodiment of the present invention; and FIG. 2 is a schematic cross-sectional view illustrating a multilayered ceramic capacitor taken along line A-A′ of FIG. 1.

Referring to FIGS. 1 and 2, the multilayered ceramic capacitor according to the present embodiment may include a ceramic body 110; internal electrodes 121 and 122 formed in the ceramic body; and external electrodes 131 and 132 formed on outer surfaces of the ceramic body 110.

The ceramic body 110 may generally have a rectangular parallelepiped shape, but is not limited thereto. In addition, the ceramic body 110 may have a size of 0.6 mm×0.3 mm and may be a multilayered ceramic capacitor having many layers and high capacitance of 2.2 μF or more. However, the present invention is not limited thereto.

The ceramic body 110 may be formed by stacking a plurality of dielectric layers 111. The plurality of dielectric layers 111 configuring the ceramic body 110 are in a sintered state and may be integrated such that boundaries between dielectric layers adjacent to each other may not be readily apparent.

The dielectric layer 111 may be formed by sintering a ceramic green sheet including a ceramic powder.

The ceramic powder is not specifically limited as far as it is generally used in the art. As the ceramic powder, a BaTiO₃-based ceramic powder may be used. However, the present invention is not limited thereto. An example of the BaTiO₃-based ceramic powder may include (Ba₁₋ₓCaₓ)TiO₃, Ba (Ti_{1-y}Ca_{y})O₃, (Ba₁₋ₓCaₓ)(Ti_{1-y}Zr_{y})O₃, or Ba (Ti_{1-y}Zr_{y}) O₃, or the like, having Ca, Zr, or the like, introduced in BaTiO₃, but is not limited thereto. An average particle size of the ceramic powder may be 1.0 μM or less, but is not limited thereto.

In addition, the ceramic green sheet may include a transition metal, a rare-earth element, Mg, Al, or the like, in addition to the ceramic powder.

A thickness of the dielectric layer 111 may be appropriately changed according to a capacitance design of the multilayered ceramic capacitor. For example, the thickness of the dielectric layer 111 formed between the internal electrodes 121 and 122 adjacent to each other after the sintering process may be 1.0 μm or less, but is not limited thereto.

The internal electrodes 121 and 122 may be formed in the ceramic body 110. The internal electrodes 121 and 122 may be formed on the dielectric layer 111, stacked and sintered to thereby have the dielectric layer interposed therebetween in the ceramic body 110.

The internal electrodes may be formed in a pair of a first internal electrode 121 and a second internal electrode 122 having different polarity, and disposed to face each other in a direction in which the dielectric layers are stacked. Distal ends of the first and second internal electrodes 121 and 122 may be alternately exposed to surfaces of the ceramic body 110.

Each of the thicknesses of the internal electrodes 121 and 122 may be appropriately determined according to a use thereof, or the like, and, for example, may be 1.0 μM or less. Otherwise, the thickness thereof may be selected within a range of 0.1 to 1.0 μm.

The internal electrodes 121 and 122 may be formed by using the conductive paste for the internal electrode according to the embodiment of the present invention. The conductive paste for the internal electrode according to the embodiment of the present invention may include a metal powder; and a chrome (Cr) or cobalt (Co) powder having a melting point higher than that of the metal powder. A detailed description thereof will be provided below.

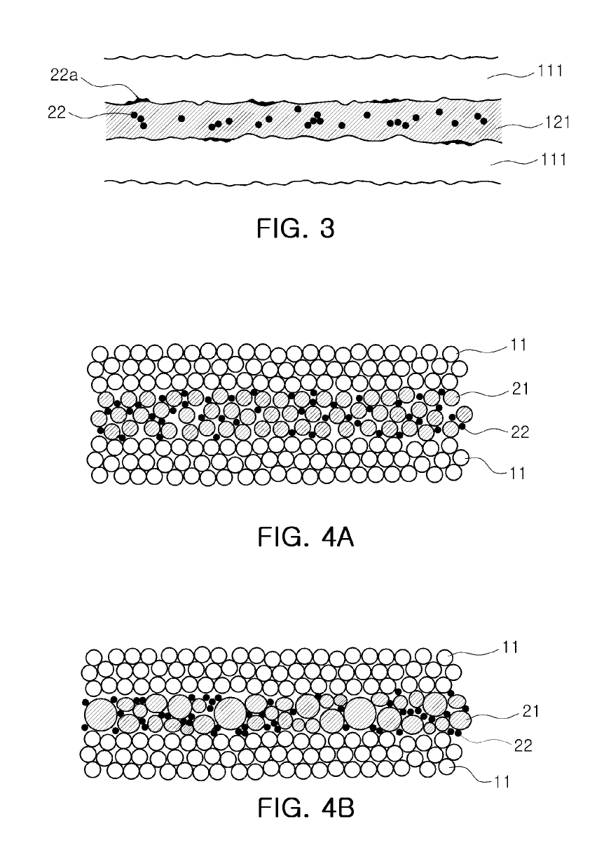

FIG. 3 is a partially enlarged view schematically illustrating an internal electrode 121 according to the embodiment of the present invention. Referring to FIG. 3, the internal electrode 121 according to the embodiment of the present invention may include the chrome (Cr) or cobalt (Co) powder having a melting point higher than that of the metal powder trapped in the internal electrode.

The chrome (Cr) or cobalt (Co) powder 22 having a melting point higher than that of the metal powder may be trapped at an interface, that is, a grain boundary of the metal grain forming the internal electrode.

In addition, the chrome (Cr) or cobalt (Co) powder may be partially oxidized.

The chrome (Cr) or cobalt (Co) powder 22 having a melting point higher than that of the metal powder has a melting point higher than that of the metal powder forming the internal electrode and may be trapped at the interface of the metal grain in the sintering process of the metal powder.

In addition, a metal layer 22a formed of the chrome (Cr) or cobalt (Co) powder having a melting point higher than that of the metal powder may be formed in one region of one surface of the internal electrode 121, that is, one region of the interface between the dielectric layer 111 and the internal electrode 121.

In addition, the chrome (Cr) or cobalt (Co) powder may be partially oxidized.

Adhesion between the internal electrode and the dielectric layer may be enhanced due to the high melting point metal layer 22a.

The high melting point metal layer 22a may function as a conductor, such that the capacitance of the multilayered ceramic capacitor may not be decreased.

It can be explicated by the conductive paste composition for the internal electrode and a method of forming the internal electrode, which will be described hereinafter.

According to the embodiment of the present invention, the external electrodes 131 and 132 may be formed on outer surfaces of the ceramic body 110, and electrically connected to the internal electrodes 121 and 122. More specifically, the first external electrode 131 electrically connected to the first internal electrode 121 exposed to one surface of the ceramic body 110 and the second external electrode 132 electrically connected to the second internal electrode 122 exposed to the other surface of the ceramic body 110 may be provided.

In addition, although not shown, the first and second internal electrodes may be exposed to at least one surface of the ceramic body. In addition, the first and second internal electrodes may be exposed to the same surface of the ceramic body.

The external electrodes 131 and 132 may be formed by using the conductive paste including a conductive material. An example of the conductive materials included in the conductive paste may include Ni, Cu, or alloys thereof, but is not limited thereto. Each of the thicknesses of the internal electrodes 131 and 132 may be appropriately determined according to a use thereof, or the like, for example, may be 10 to 50 μm.

Hereinafter, a conductive paste composition for an internal electrode of a multilayered ceramic electronic component according to the embodiment of the present invention will be described.

FIGS. 4A and 4B are diagrams schematically illustrating a sintering shrinkage behavior of the conductive paste for the internal electrode according to the embodiment of the present invention. Hereinafter, a description will be described with reference to FIGS. 4A and 4B.

The conductive paste composition for the internal electrode according to the embodiment of the present invention may include a metal powder 21; and a chrome (Cr) or cobalt (Co) powder 22 having a melting point higher than that of the metal powder.

With the conductive paste composition for the internal electrode according to the embodiment of the present invention, a sintering shrinkage temperature of the internal electrode may be increased, and connectivity of the internal electrode may be improved.

Kinds of the metal powder 21 included in the conductive paste composition are not specifically limited. For example, a base metal may be used.

The metal powder may include at least one selected from the group consisting of nickel (Ni), manganese (Mn), chrome (Cr), cobalt (Co), aluminum (Al) and alloys thereof, but is not limited thereto.

In addition, an average particle size of the metal powder 21 may be 400 nm or less, but is not limited thereto.

More specifically, the average particle size of the metal powder 21 may be 50 to 400 nm.

The chrome (Cr) or cobalt (Co) powder 22 included in the conductive paste composition may have a melting point higher than that of the metal powder 21.

The chrome (Cr) or cobalt (Co) powder 22 may be used by mixing one or more kinds thereof, but is not limited thereto.

The chrome (Cr) or cobalt (Co) powder 22 may have an average particle size smaller than that of the metal powder 21.

The chrome (Cr) or cobalt (Co) powder 22 may have an average particle size of 10 to 100 nm, but is not limited thereto.

The chrome (Cr) or cobalt (Co) powder 22 has an average particle size smaller than that of the metal powder 21, thereby being distributed between the metal powder particles 21.

The chrome (Cr) or cobalt (Co) powder 22 may delay a sintering shrinkage initiation temperature of the metal powder 21 and suppress sintering shrinkage of the metal powder 21.

More specifically, at the time of sintering shrinkage of the metal powder 21, the chrome (Cr) or cobalt (Co) powder 22 may prevent contact between the metal powder particles to suppress grain growth of the metal powder.

For example, a melting point of chrome (Cr) is about 1890° C., a melting point of cobalt (Co) is 1768° C., and in the case of chrome oxide (Cr₂O₃), a melting point thereof is 2435° C., higher than that of a metal.

Therefore, it may be appreciated that the chrome (Cr) or cobalt (Co) powder may be effective in suppressing the sintering shrinkage of the metal powder 21.

According to the embodiment of the present invention, the chrome (Cr) or cobalt (Co) powder 22 has a content of 1 to 20 parts by weight based on 100 parts by weight of the metal powder 21.

In the case in which the content of the chrome (Cr) or cobalt (Co) powder 22 is less than 1 part by weight, the connectivity of the electrode may be deteriorated, and in the case in which the content of the chrome (Cr) or cobalt (Co) powder 22 is more than 20 parts by weight, an amount of the oxide-type metal present in the interface between the internal electrode and the dielectric layer may be increased to thereby decrease the capacitance.

The conductive paste composition for the internal electrode according to the embodiment of the present invention may additionally include a dispersant, a binder, a solvent, or the like.

The binder may be polyvinylbutyral, a cellulose-based resin, or the like, but is not limited thereto. The polyvinylbutyral may have strong adhesion to thereby improve adhesive strength between the conductive paste for the internal electrode and the ceramic green sheet.

The cellulose-based resin, having a chair-type structure, is rapidly returned by elasticity at the time of modification thereof. The cellulose-based resin may be included to secure a flat printed surface.

The solvent may be butylcarbitol, kerosene or a terpineol-based solvent, but is not limited thereto.

In general, the conductive paste composition for the internal electrode is printed and multilayered on the ceramic green sheet, and then co-fired with the ceramic green sheet.

In addition, in the case in which a base metal is used as the internal electrode and the firing process is performed in the air, the internal electrode may be oxidized.

Therefore, a co-firing process of the ceramic green sheet and the internal electrode may be performed under a reduction atmosphere.

The dielectric layer of the multilayered ceramic capacitor may be formed by firing the ceramic green sheet at a high temperature of about 1100° C. or more.

In the case in which the base metal such as Ni, or the like, is used in the internal electrode, the sintering shrinkage is generated while being oxidized from 400° C., which is a low temperature, and may be rapidly fired at 1000° C. or more. In the case in which the internal electrode is rapidly fired, the electrode may be agglomerated or disconnected due to overfiring of the internal electrode, and the connectivity and capacitance of the internal electrode may be deteriorated. In addition, after the firing process, defects such as cracks in an internal structure of the multilayered ceramic capacitor may be generated.

Therefore, a sintering initiation temperature of the metal powder in which the sintering process starts at a relatively lower temperature of 400 to 500° C. may be delayed by as much as possible to allow for a difference in sintering shrinkage rates with the dielectric.

FIGS. 4A and 4B are diagrams schematically illustrating sintering shrinkage behavior of the conductive paste for the internal electrode according to the embodiment of the present invention. FIG. 4A shows an initial firing process, that is, a state thereof before the sintering shrinkage of the metal powder 21 starts, and FIG. 4B schematically shows a state in which the sintering shrinkage of the metal powder 21 progresses through an increase in temperature.

In FIGS. 4A and 4B, the ceramic powder 11 may form the dielectric layer 111 shown in FIG. 2 through the sintering process.

Referring to FIGS. 4A and 4B, at the time of the initial sintering process, the metal powder 21 may shrink, the chrome (Cr) or cobalt (Co) powder 22 may be discharged between the metal powder particles to move toward the ceramic powder 11.

In general, before the ceramic powder is shrunken, the metal powder may be sintered to form the internal electrode, and the internal electrode may be agglomerated during the shrinkage of the ceramic powder, such that the connectivity of the internal electrode may be deteriorated.

However, according to the embodiment of the present invention, in the case in which the particulate chrome (Cr) or cobalt (Co) powder 22 having a firing temperature higher than that of the metal powder 21 is uniformly dispersed in the metal powder 21, the sintering of the metal powder 21 may be suppressed until a temperature of about 1000° C. or more. The sintering of the metal powder 21 may be suppressed until about 1000° C. as much as possible, and the sintering of the ceramic powder 11 may then be initiated.

When the ceramic powder 11 is densified, densification of the internal electrode is also initiated and the sintering process may be rapidly performed. Here, in the case of controlling a rate of a temperature raise, the chrome (Cr) or cobalt (Co) powder 22 may not be discharged between the metal powder particles 21 and, as shown in FIG. 3, trapped in a grain boundary of the metal powder 21 to suppress a grain growth of the metal powder 21. Therefore, an agglomeration phenomenon of the internal electrode may be suppressed, such that the connectivity of the internal electrode may be increased.

In addition, some of the chrome (Cr) or cobalt (Co) powder 22 may be pushed to a surface of the internal electrode, thereby being distributed in a small amount at the interface between the dielectric layer 111 and the internal electrode 121. In the case in which the chrome (Cr) or cobalt (Co) powder is present at the interface between the dielectric layer 111 and the internal electrode 121, the connectivity of the electrode may be excellent, to thereby increase an effective electrode area.

In addition, the chrome (Cr) or cobalt (Co) powder 22 may form a metal layer 22a.

The metal layer 22a formed of the chrome (Cr) or cobalt (Co) powder may function as a conductor according to a content ratio of the metal. In addition, in the case of controlling a content of the chrome (Cr) or cobalt (Co) powder, even in the case that some of the chrome (Cr) or cobalt (Co) powder is present in an oxide, the capacitance of the multilayered ceramic capacitor may not be significantly decreased.

Recently, as multilayered ceramic capacitors have been miniaturized and lightened, the internal electrodes thereof have been thinned. In order to form a thinned internal electrode, relatively more particulate metal powder may be used. However, in this case, it may be difficult to control the sintering-shrinkage of the metal powder and to secure the connectivity of the internal electrode.

However, according to the embodiment of the present invention, the chrome (Cr) or cobalt (Co) powder having a melting point higher than that of the metal powder is included in the conductive paste for the internal electrode, whereby the sintering shrinkage of the metal powder forming the internal electrode may be suppressed.

In addition, the chrome (Cr) or cobalt (Co) powder is trapped in the internal electrode to improve the connectivity of the internal electrode, thereby forming the thinner internal electrode.

Hereinafter, a method of manufacturing a multilayered ceramic capacitor according to another embodiment of the present invention will be described.

According to the embodiment of the present invention, a plurality of ceramic green sheets may be prepared. A ceramic powder, a binder, a solvent, and the like, may be mixed to prepare a slurry, and the thus obtained slurry may be used to manufacture a sheet type ceramic green sheet having thickness on a μm level by a doctor blade method. The ceramic green sheet then may be sintered to form one dielectric layer 111, as shown in FIG. 2.

Next, a conductive paste for an internal electrode may be applied to form an internal electrode pattern on the ceramic green sheet. The internal electrode pattern may be formed by a screen printing method or a gravure printing method.

The conductive paste composition for the internal electrode may be used according to the embodiment of the present invention, and specific components and contents thereof are as described above.

After that, the plurality of ceramic green sheets are stacked and pressurized in a stacking direction, thereby compressing the multilayered ceramic green sheets and the conductive paste for the internal electrode. As described above, a ceramic multilayered body in which the ceramic green sheets and the internal electrodes are alternately multilayered may be manufactured.

Then, the ceramic multilayered body may be cut into chips corresponding to individual capacitors. Here, the ceramic multilayered body may be cut so that one ends of the internal electrode patterns are alternately exposed through the side thereof. Then, the chipped multilayered body may be fired to manufacture a ceramic body. As described above, the firing process may be performed under a reduction atmosphere. In addition, the firing process may be performed by controlling the raising-temperature rate. The rate of temperature raise may be 30° C./60 s to 50° C./60 s, but is not limited thereto.

Then, external electrodes may be formed to cover surfaces of the ceramic body and be electrically connected to the internal electrodes exposed to the surfaces of the ceramic body. After that, a plating treatment may be performed using nickel (Ni), tin (Sn), or the like, on a surface of the external electrode.

As described above, the chrome (Cr) or cobalt (Co) powder 22 may be trapped at a grain boundary of the internal electrode 121, such that the connectivity of the internal electrode may be improved.

In addition, the metal layer 22a formed of the chrome (Cr) or cobalt (Co) powder may be formed in one region of the interface between the dielectric layer 111 and the internal electrode 121. The metal layer 22a may function as a conductor, such that the capacitance of the multilayered ceramic capacitor may not be decreased.

According to the embodiment of the present invention, the conductive paste composition for the internal electrode was prepared, and the prepared conductive paste composition for the internal electrode was used to manufacture the multilayered ceramic capacitor. In the conductive paste composition, a nickel powder was used for the metal powder, and specific kinds and contents of the high melting point metal are described in Table 1 below.

[Evaluation]

The connectivity of the electrode of the multilayered ceramic capacitor is evaluated by a value obtained by calculating a ratio of a length of the internal electrode, excepting gaps, to an entire length of the internal electrode in one cross-section of the internal electrode, with a following standard, and the evaluation results are shown in Table 1 below.

□: excellent (Electrode Connectivity 85% or more)

∘: good (Electrode Connectivity 75% to less than 85%)

x: defective (Electrode Connectivity less than 75%)

The electrical characteristics of the multilayered ceramic capacitor were evaluated as to whether or not withstand voltage characteristics such as a target capacitance, DF, BDV, IR, accelerated life time, or the like, were implemented. The electrical characteristics of 100 chips were measured, and evaluated by a following standard according to the number of the chips appropriate for the standard, and the evaluation results are shown in Table 1 below.

□: excellent (number of chips appropriate for standard 85 or more)

∘: good (number of chips appropriate for standard 75 to less than 85)

x: defective (number of chips appropriate for standard less than 75)

TABLE 1

| | Nickel | | Average | | | |
|---|---|---|---|---|---|---|
| | (Ni) | | Particle | | | |
| | Average | High | Size of High | | | |
| | Particle | Melting | Melting | Content | Electrode | |
| | Size | Point | Point Metal | (Parts by | Connectivity | Electrical |
| Sample | (nm) | Metal | (nm) | Weight/Ni) | (%) | Characteristics |
| 1 | 50 | Cr | 20 | 1.0 | ∘ | ∘ |
| 2 | 50 | Cr | 30 | 3.0 | ∘ | □ |
| 3 | 50 | Cr | 50 | 10.0 | □ | □ |
| 4 | 50 | Cr | 50 | 20 | ∘ | ∘ |
| 5* | 50 | Cr | 50 | 25 | □ | x |
| 6* | 100 | Cr | 10 | 5.0 | x | x |
| 7 | 100 | Cr | 20 | 1.0 | □ | □ |
| 8 | 100 | Cr | 50 | 10.0 | ∘ | ∘ |
| 9 | 100 | Cr | 70 | 7.0 | ∘ | ∘ |
| 10 | 100 | Cr | 100 | 15 | ∘ | ∘ |
| 11* | 200 | Cr | 20 | 0.7 | x | x |
| 12 | 200 | Cr | 50 | 2.0 | ∘ | □ |
| 13 | 200 | Cr | 100 | 10 | ∘ | ∘ |
| 14* | 200 | Cr | 100 | 22 | x | ∘ |
| 15* | 200 | Cr | 250 | 10 | x | x |
| 16 | 50 | Co | 20 | 1.0 | ∘ | ∘ |
| 17 | 50 | Co | 30 | 3.0 | ∘ | □ |
| 18 | 50 | Co | 50 | 10.0 | □ | □ |
| 19 | 50 | Co | 50 | 20 | ∘ | ∘ |
| 20* | 50 | Co | 50 | 25 | □ | x |
| 21* | 100 | Co | 10 | 5.0 | x | x |
| 22 | 100 | Co | 20 | 1.0 | □ | □ |
| 23 | 100 | Co | 50 | 10.0 | ∘ | ∘ |
| 24 | 100 | Co | 70 | 7.0 | ∘ | ∘ |
| 25 | 100 | Co | 100 | 15 | ∘ | ∘ |
| 26* | 200 | Co | 20 | 0.7 | x | x |
| 27 | 200 | Co | 50 | 2.0 | ∘ | □ |
| 28 | 200 | Co | 100 | 10 | ∘ | ∘ |
| 29* | 200 | Co | 100 | 22 | x | ∘ |
| 30* | 200 | Co | 250 | 10 | x | x |

Referring to FIG. 1 above, it may be appreciated that the contents of the high melting point metal were controlled according to kinds thereof, and in the case in which the chrome (Cr) or cobalt (Co) powder content was 1.0 to 20 parts by weight based on 100 parts by weight of the metal powder, the connectivity of the electrode in 75% or more could be implemented and the electrical characteristics were excellent.

As set forth above, with the conductive paste composition for the internal electrode according to the embodiment of the present invention, the sintering shrinkage temperature of the internal electrode may be increased, and the connectivity of the internal electrode may be improved.

With the conductive paste composition for the internal electrode according to the embodiment of the present invention, the chrome (Cr) or cobalt (Co) powder having a melting point higher than that of the metal powder may be easily dispersed in the metal powder, and the sintering of the metal powder may be suppressed until about 1000° C. or more.

According to the embodiment of the present invention, in the case of controlling the raising-temperature rate of the firing process, the high melting point metal powder in the conductive paste composition for the internal electrode may not be discharged between the metal powder particles and trapped at a grain boundary of the metal powder. Therefore, the agglomeration phenomenon of the internal electrode is suppressed, such that the connectivity of the internal electrode may be increased.

In addition, the chrome (Cr) or cobalt (Co) powder may be present in one region of the interface between the dielectric layer and the internal electrode layer of the ceramic electronic component.

Further, according to the embodiment of the present invention, the conductive paste for the internal electrode includes the high melting point metal powder to trap the high melting point metal powder in the internal electrode layer, such that the connectivity of the internal electrode is improved, whereby the internal electrode layer may be thinned.

While the present invention has been shown and described in connection with the embodiments, it will be apparent to those skilled in the art that modifications and variations can be made without departing from the spirit and scope of the invention as defined by the appended claims.

What is claimed is:

1. A conductive paste composition for an internal electrode of a multilayered ceramic electronic component comprising:
a metal powder; and
a chrome (Cr) or cobalt (Co) powder having a melting point higher than that of the metal powder.

2. The conductive paste composition for an internal electrode of a multilayered ceramic electronic component of claim 1, wherein the chrome (Cr) or cobalt (Co) powder has a content of 1 to 20 parts by weight based on 100 parts by weight of the metal powder.

3. The conductive paste composition for an internal electrode of a multilayered ceramic electronic component of claim 1, wherein the metal powder is at least one selected from the group consisting of nickel (Ni), manganaese (Mn), chromium (Cr), cobalt (Co), aluminum (Al), and alloys thereof.

4. The conductive paste composition for an internal electrode of a multilayered ceramic electronic component of claim 1, wherein the metal powder has an average particle size of 50 to 400 nm.

5. The conductive paste composition for an internal electrode of a multilayered ceramic electronic component of claim 1, wherein the chrome (Cr) or cobalt (Co) powder has an average particle size of 10 to 100 nm.

6. A multilayered ceramic electronic component comprising:
a ceramic body; and
internal electrode layers formed in the ceramic body,
the internal electrode layers including a chrome (Cr) or cobalt (Co) powder trapped therein, the chrome (Cr) or cobalt (Co) powder having a melting point higher than that of a metal powder forming the internal electrode layers.

7. The multilayered ceramic electronic component of claim 6, wherein the chrome (Cr) or cobalt (Co) powder is partially oxidized.

8. The multilayered ceramic electronic component of claim 6, wherein the internal electrode layers have a metal layer formed of the chrome (Cr) or cobalt (Co) powder on an interface thereof.

9. The multilayered ceramic electronic component of claim 8, wherein the chrome (Cr) or cobalt (Co) powder is partially oxidized.

10. The multilayered ceramic electronic component of claim 6, wherein the metal powder is at least one selected from the group consisting of nickel (Ni), manganaese (Mn), chromium (Cr), cobalt (Co), aluminum (Al), and alloys thereof.

11. The multilayered ceramic electronic component of claim 6, wherein the chrome (Cr) or cobalt (Co) powder has a content of 1 to 20 parts by weight based on 100 parts by weight of the metal powder.

12. The multilayered ceramic electronic component of claim 6, wherein the metal powder has an average particle size of 50 to 400 nm.

13. The multilayered ceramic electronic component of claim 6, wherein the chrome (Cr) or cobalt (Co) powder has an average particle size of 10 to 100 nm.
